(19) United States
(12) Patent Application Publication
(10) Pub. No.: US 2024/0196539 A1
(43) Pub. Date: Jun. 13, 2024

(54) PRINTED CIRCUIT BOARD ASSEMBLY WITH REDUCED TOTAL HEIGHT

(71) Applicant: MEDIATEK INC., Hsin-Chu (TW)

(72) Inventors: Chun-Ping Chen, Hsinchu City (TW); Pei-San Chen, Hsinchu City (TW); Hui-Chi Tang, Hsinchu City (TW)

(73) Assignee: MEDIATEK INC., Hsin-Chu (TW)

(21) Appl. No.: 18/533,234

(22) Filed: Dec. 8, 2023

Related U.S. Application Data
(60) Provisional application No. 63/386,924, filed on Dec. 12, 2022.

(51) Int. Cl. H05K 1/18; H01L 23/00; H01L 23/498; H01L 25/16

(52) U.S. Cl. CPC H05K 1/183; H01L 23/49816; H01L 24/13; H01L 24/16; H01L 25/16; H01L 2224/13005; H01L 2224/16227; H01L 2924/2076; H05K 1/021; H05K 2201/09072; H05K 2201/10015; H05K 2201/10378; H05K 2201/10515; H05K 2201/1053; H05K 2201/10734

(57) ABSTRACT

A printed circuit board assembly including a substrate having a first surface and a second surface opposite to the first surface, wherein the substrate has a first thickness; a cavity disposed within a chip module mounting region of the substrate on the first surface that caves in towards the second surface, wherein the chip module mounting region of the substrate has a second thickness, wherein the second thickness is smaller than the first thickness; a plurality of bonding pads in the cavity; and a chip module mounted in the cavity and electrically connected to the substrate through the plurality of bonding pads.

### CROSS REFERENCE TO RELATED APPLICATIONS

This application claims the benefit of U.S. Provisional Application No. 63/386,924, filed on Dec. 12, 2022. The content of the application is incorporated herein by reference.

### BACKGROUND

The present disclosure relates generally to the field of semiconductor technology. More particularly, the present disclosure relates to a printed circuit board assembly with reduced total height.

Integrated circuit substrates have recently gained prominence. It results from emerging integrated circuit types such as chip-scale (CSP) and ball grid array packages (BGA packages). Such IC packages necessitate novel package carriers.

PCB thickness varies widely, ranging from 0.008 inches to 0.240 inches. Selecting the appropriate PCB thickness depends on specific applications and requirements. For example, in lightweight devices or those needing a slimmer profile, a thinner 1.0 mm thickness might be employed. For certain specialized purposes, a 2.0 mm (0.079 inches) or even thicker PCB could be necessary to accommodate extra components or specific mechanical demands.

A printed circuit board assembly (PCBA) describes the finished board after all the components have been soldered and installed on a printed circuit board (PCB). It is desirable in this technical field to provide a printed circuit board assembly with reduced total height to meet the requirements of the future electronic products.

### SUMMARY

It is one object of the present invention to provide a printed circuit board assembly with reduced total height in order to solve the prior art deficiencies or shortcomings.

One aspect of the invention provides a printed circuit board assembly including a substrate having a first surface and a second surface opposite to the first surface, wherein the substrate has a first thickness; a cavity disposed within a chip module mounting region of the substrate on the first surface that caves in towards the second surface, wherein the chip module mounting region of the substrate has a second thickness, wherein the second thickness is smaller than the first thickness; a plurality of bonding pads in the cavity; and a chip module mounted in the cavity and electrically connected to the substrate through the plurality of bonding pads.

According to some embodiments, the chip module is a multi-chip module.

According to some embodiments, the multi-chip module comprises a module board having a third surface directly facing the first surface of the substrate, and a fourth surface opposite to the third surface.

According to some embodiments, the multi-chip module further comprises a plurality of integrated circuit chips mounted on the fourth surface through a plurality of first ball grid array (BGA) balls.

According to some embodiments, the module board is mounted on the plurality of bonding pads through a plurality of second ball grid array (BGA) balls.

According to some embodiments, the first BGA balls have a first width and the second BGA balls have a second width, wherein the second width is greater than the first width.

According to some embodiments, the first width is about 0.2 mm and the second width is about 0.63 mm.

According to some embodiments, the multi-chip module further comprises a plurality of capacitors mounted on the third surface of the module board.

According to some embodiments, the plurality of capacitors has a thickness that is greater than or equal to 0.2 mm.

According to some embodiments, the printed circuit board assembly further includes a through hole disposed in the chip module mounting region of the substrate, wherein the through hole is positioned directly under the plurality of capacitors.

Another aspect of the invention provides a printed circuit board assembly including a substrate having a first surface and a second surface opposite to the first surface, wherein the substrate has a first thickness; a cavity disposed within a chip module mounting region of the substrate on the first surface that caves in towards the second surface, wherein the chip module mounting region of the substrate has a second thickness, wherein the second thickness is smaller than the first thickness; a plurality of bonding pads in the cavity; a chip module mounted in the cavity and electrically connected to the substrate through the plurality of bonding pads; a through hole disposed in the chip module mounting region of the substrate; and a heat sink disposed in the through hole and thermally coupled to the chip module.

According to some embodiments, the chip module is a multi-chip module.

According to some embodiments, the multi-chip module comprises a module board having a third surface directly facing the first surface of the substrate, and a fourth surface opposite to the third surface.

According to some embodiments, the multi-chip module further comprises a plurality of integrated circuit chips mounted on the fourth surface through a plurality of first ball grid array (BGA) balls.

According to some embodiments, the module board is mounted on the plurality of bonding pads through a plurality of second ball grid array (BGA) balls.

According to some embodiments, the first BGA balls have a first width and the second BGA balls have a second width, wherein the second width is greater than the first width.

According to some embodiments, the first width is about 0.2 mm and the second width is about 0.63 mm.

According to some embodiments, the multi-chip module further comprises a plurality of capacitors mounted on the third surface of the module board.

According to some embodiments, the plurality of capacitors has a thickness that is greater than or equal to 0.2 mm.

According to some embodiments, the through hole is positioned directly under the plurality of capacitors, and wherein the heat sink is in direct contact with the plurality of capacitors.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings:

FIG. 1 is a schematic, cross-sectional diagram showing an exemplary printed circuit board assembly according to an embodiment of the disclosure; and

FIG. 2 is a schematic, cross-sectional diagram showing an exemplary printed circuit board assembly according to another embodiment of the disclosure.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, chemical, electrical, and procedural changes may be made without departing from the spirit and scope of the present disclosure. The following detailed description is, therefore, not to be taken in a limiting sense, and the scope of embodiments of the present invention is defined only by the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

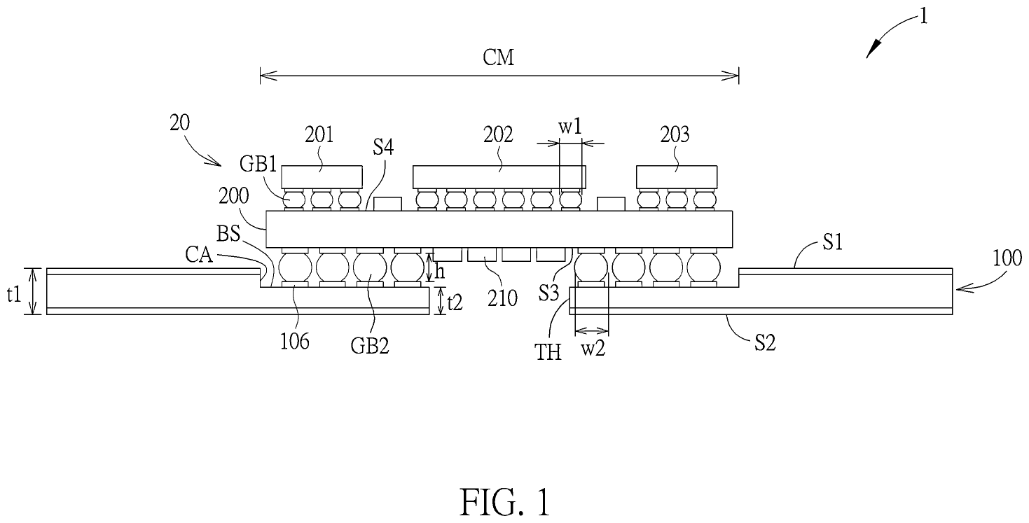

Please refer to FIG. 1. FIG. 1 is a schematic, cross-sectional diagram showing an exemplary printed circuit board assembly according to an embodiment of the disclosure. As shown in FIG. 1, the printed circuit board assembly 1 comprises a substrate 100 having a first surface S1 and a second surface S2 opposite to the first surface S1. According to an embodiment, for example, the substrate 100 is a printed circuit board (PCB). According to an embodiment, for example, the substrate 100 may be a cored substrate, but is not limited thereto. A core is a dielectric material commonly composed of epoxy resin and glass fiber weave. According to an embodiment, for example, the substrate 100 may be a high-density interconnect (HDI) PCB, but is not limited thereto. For the sake of simplicity, the interconnect structures of the substrate 100 such as plated through holes, micro-vias, built-up laminations, and traces are not illustrated in the figures.

According to an embodiment, for example, the substrate 100 has a first thickness t1 of about 1.0-3.0 mm between the first surface S and the second surface S2. According to an embodiment, for example, the first thickness t1 may be about 1.6 mm. According to an embodiment, for example, the substrate 100 comprises a chip module mounting region CM.

According to an embodiment, a cavity CA is disposed within the chip module mounting region CM of the substrate 100 on the first surface S1. The cavity CA caves in towards the second surface S2. The chip module mounting region CM of the substrate 100 has a second thickness t2. According to an embodiment, the second thickness t2 is smaller than the first thickness t1. According to an embodiment, for example, the second thickness t2 may be about 1.2-1.3 mm.

According to an embodiment, a plurality of bonding pads 106 is disposed on a bottom surface BS of the cavity CA. According to an embodiment the plurality of bonding pads 106 may comprises copper pads, but is not limited thereto. According to an embodiment, for example, the plurality of bonding pads 106 may have a pad pitch of about 1.27 mm, but is not limited thereto.

According to an embodiment, a chip module 20 is mounted in the cavity CA and is electrically connected to the substrate 100 through the plurality of bonding pads 106. According to some embodiments, for example, the chip module 20 is a multi-chip module comprising a module board 200 having a third surface S3 directly facing the first surface S1 of the substrate 100, and a fourth surface S4 opposite to the third surface S3. According to an embodiment, for example, the module board 200 may be a package substrate. According to an embodiment, the third surface S3 is higher than the first surface S1.

According to an embodiment, the multi-chip module further comprises a plurality of integrated circuit chips 201-203 mounted on the fourth surface S4 through a plurality of first ball grid array (BGA) balls GB1. According to an embodiment, for example, the plurality of integrated circuit chips 201-203 may comprise a logic chips, an analogy chip, a system-on-chip, an RF chip, or a DRAM chip, but is not limited thereto.

According to an embodiment, the module board 200 is mounted on the plurality of bonding pads 106 through a plurality of second ball grid array (BGA) balls GB2. According to an embodiment, for example, the plurality of second BGA balls GB2 may have a ball pitch of about 1.27 mm and a ball height h of about 0.5 mm, but not limited thereto. According to an embodiment, the first BGA balls GB1 have a first width w1 and the second BGA balls have a second width w2. According to some embodiments, for example, the second width w2 is greater than the first width w1. According to some embodiments, for example, the first width w1 is about 0.2 mm and the second width w2 is about 0.36 mm.

According to an embodiment, the multi-chip module 20 further comprises a plurality of capacitors 210 mounted on the third surface S3 of the module board 200. According to an embodiment, the plurality of capacitors 210 may be decoupling capacitors, but is not limited thereto. According to an embodiment, for example, the plurality of capacitors 210 may have a thickness that is greater than or equal to 0.2 mm, for example, 0.4 mm.

According to an embodiment, the printed circuit board assembly 1 further includes a through hole TH disposed in the chip module mounting region CM of the substrate 100. According to an embodiment, the through hole TH is positioned directly under the plurality of capacitors 210. According to an embodiment, the plurality of second BGA balls GB2 is disposed around the through hole TH.

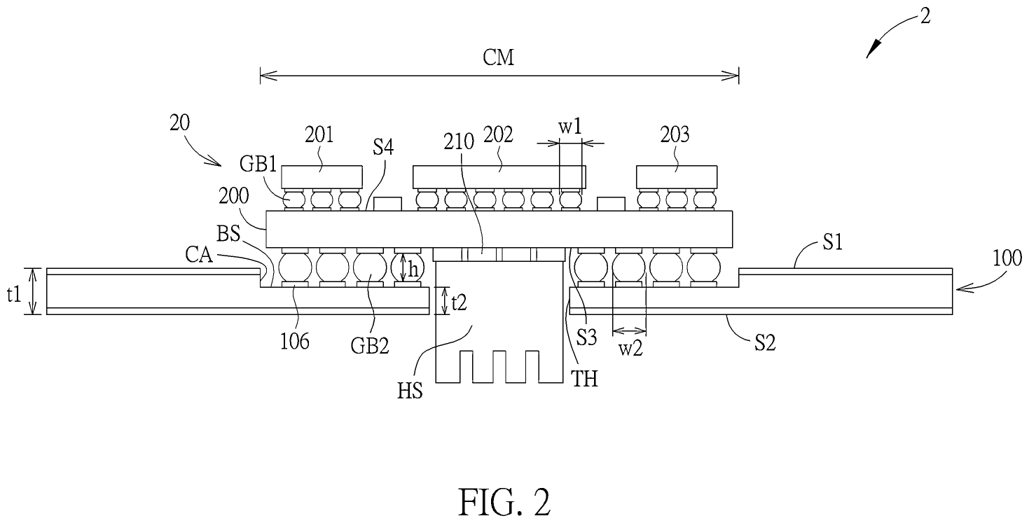

Please refer to FIG. 2. FIG. 2 is a schematic, cross-sectional diagram showing an exemplary printed circuit board assembly according to another embodiment of the disclosure. As shown in FIG. 2, likewise, the printed circuit board assembly 2 comprises a substrate 100 having a first surface S1 and a second surface S2 opposite to the first surface S1. According to an embodiment, for example, the substrate 100 is a printed circuit board (PCB). According to an embodiment, for example, the substrate 100 may be a cored substrate, but is not limited thereto. According to an embodiment, for example, the substrate 100 may be a high-density interconnect (HDI) board, but is not limited thereto. For the sake of simplicity, the interconnect structures of the substrate 100 such as plated through holes, micro-vias, built-up laminations, and traces are not illustrated in the figures.

According to an embodiment, for example, the substrate 100 has a first thickness t1 of about 1.0-3.0 mm between the first surface S1 and the second surface S2. According to an embodiment, for example, the first thickness t1 may be about 1.6 mm. According to an embodiment, for example, the substrate 100 comprises a chip module mounting region CM.

According to an embodiment, a cavity CA is disposed within the chip module mounting region CM of the substrate 100 on the first surface S1. The cavity CA caves in towards the second surface S2. The chip module mounting region CM of the substrate 100 has a second thickness t2. According to an embodiment, the second thickness t2 is smaller than the first thickness t1. According to an embodiment, for example, the second thickness t2 may be about 1.2-1.3 mm.

According to an embodiment, a plurality of bonding pads 106 is disposed on a bottom surface BS of the cavity CA. According to an embodiment the plurality of bonding pads 106 may comprises copper pads, but is not limited thereto. According to an embodiment, for example, the plurality of bonding pads 106 may have a pad pitch of about 1.27 mm, but is not limited thereto.

According to an embodiment, a chip module 20 is mounted in the cavity CA and is electrically connected to the substrate 100 through the plurality of bonding pads 106. According to some embodiments, for example, the chip module 20 is a multi-chip module comprising a module board 200 having a third surface S3 directly facing the first surface S1 of the substrate 100, and a fourth surface S4 opposite to the third surface S3. According to an embodiment, for example, the module board 200 may be a package substrate. According to an embodiment, the third surface S3 is higher than the first surface S1.

According to an embodiment, the multi-chip module further comprises a plurality of integrated circuit chips 201-203 mounted on the fourth surface S4 through a plurality of first ball grid array (BGA) balls GB1. According to an embodiment, for example, the plurality of integrated circuit chips 201-203 may comprise a logic chips, an analogy chip, a system-on-chip, an RF chip, or a DRAM chip, but is not limited thereto.

According to an embodiment, the module board 200 is mounted on the plurality of bonding pads 106 through a plurality of second ball grid array (BGA) balls GB2. According to an embodiment, for example, the plurality of second BGA balls GB2 may have a ball pitch of about 1.27 mm and a ball height h of about 0.5 mm, but not limited thereto. According to an embodiment, the first BGA balls GB1 have a first width w1 and the second BGA balls have a second width w2. According to some embodiments, for example, the second width w2 is greater than the first width w1. According to some embodiments, for example, the first width w1 is about 0.2 mm and the second width w2 is about 0.36 mm.

According to an embodiment, the multi-chip module 20 further comprises a plurality of capacitors 210 mounted on the third surface S3 of the module board 200. According to an embodiment, the plurality of capacitors 210 may be decoupling capacitors, but is not limited thereto. According to an embodiment, for example, the plurality of capacitors 210 may have a thickness that is greater than or equal to 0.2 mm, for example, 0.4 mm or 0.5 mm.

According to an embodiment, the printed circuit board assembly 2 further includes a through hole TH disposed in the chip module mounting region CM of the substrate 100. According to an embodiment, the through hole TH is positioned directly under the plurality of capacitors 210. According to an embodiment, the plurality of second BGA balls GB2 is disposed around the through hole TH.

According to an embodiment, the printed circuit board assembly 2 further includes a heat sink HS disposed in the through hole TH. The heat sink HS is thermally coupled to the chip module 20. According to an embodiment, the heat sink HS is in direct contact with the plurality of capacitors 210.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A printed circuit board assembly, comprising:
a substrate having a first surface and a second surface opposite to the first surface, wherein the substrate has a first thickness;
a cavity disposed within a chip module mounting region of the substrate on the first surface that caves in towards the second surface, wherein the chip module mounting region of the substrate has a second thickness, wherein the second thickness is smaller than the first thickness;
a plurality of bonding pads in the cavity; and
a chip module mounted in the cavity and electrically connected to the substrate through the plurality of bonding pads.

2. The printed circuit board assembly according to claim 1, wherein the chip module is a multi-chip module.

3. The printed circuit board assembly according to claim 2, wherein the multi-chip module comprises a module board having a third surface directly facing the first surface of the substrate, and a fourth surface opposite to the third surface.

4. The printed circuit board assembly according to claim 3, wherein the multi-chip module further comprises a plurality of integrated circuit chips mounted on the fourth surface through a plurality of first ball grid array (BGA) balls.

5. The printed circuit board assembly according to claim 4, wherein the module board is mounted on the plurality of bonding pads through a plurality of second ball grid array (BGA) balls.

6. The printed circuit board assembly according to claim 5, wherein the first BGA balls have a first width and the second BGA balls have a second width, wherein the second width is greater than the first width.

7. The printed circuit board assembly according to claim 6, wherein the first width is about 0.2 mm and the second width is about 0.63 mm.

8. The printed circuit board assembly according to claim 3, wherein the multi-chip module further comprises a plurality of capacitors mounted on the third surface of the module board.

9. The printed circuit board assembly according to claim 3, wherein the plurality of capacitors have a thickness that is greater than or equal to 0.2 mm.

10. The printed circuit board assembly according to claim 8 further comprising:
a through hole disposed in the chip module mounting region of the substrate, wherein the through hole is positioned directly under the plurality of capacitors.

11. A printed circuit board assembly, comprising:
a substrate having a first surface and a second surface opposite to the first surface, wherein the substrate has a first thickness;
a cavity disposed within a chip module mounting region of the substrate on the first surface that caves in towards the second surface, wherein the chip module mounting region of the substrate has a second thickness, wherein the second thickness is smaller than the first thickness;
a plurality of bonding pads in the cavity;
a chip module mounted in the cavity and electrically connected to the substrate through the plurality of bonding pads;
a through hole disposed in the chip module mounting region of the substrate; and
a heat sink disposed in the through hole and thermally coupled to the chip module.

12. The printed circuit board assembly according to claim 11, wherein the chip module is a multi-chip module.

13. The printed circuit board assembly according to claim 12, wherein the multi-chip module comprises a module board having a third surface directly facing the first surface of the substrate, and a fourth surface opposite to the third surface.

14. The printed circuit board assembly according to claim 13, wherein the multi-chip module further comprises a plurality of integrated circuit chips mounted on the fourth surface through a plurality of first ball grid array (BGA) balls.

15. The printed circuit board assembly according to claim 14, wherein the module board is mounted on the plurality of bonding pads through a plurality of second ball grid array (BGA) balls.

16. The printed circuit board assembly according to claim 15, wherein the first BGA balls have a first width and the second BGA balls have a second width, wherein the second width is greater than the first width.

17. The printed circuit board assembly according to claim 16, wherein the first width is about 0.2 mm and the second width is about 0.63 mm.

18. The printed circuit board assembly according to claim 13, wherein the multi-chip module further comprises a plurality of capacitors mounted on the third surface of the module board.

19. The printed circuit board assembly according to claim 13, wherein the plurality of capacitors have a thickness that is greater than or equal to 0.2 mm.

20. The printed circuit board assembly according to claim 18, wherein the through hole is positioned directly under the plurality of capacitors, and wherein the heat sink is in direct contact with the plurality of capacitors.
